(19) United States
(12) Patent Application Publication
(10) Pub. No.: US 2023/0353108 A1
(43) Pub. Date: Nov. 2, 2023

(54) INVERTING CURRENT AMPLIFICATION AND RELATED TOUCH SYSTEMS

(71) Applicant: Microchip Technology Incorporated, Chandler, AZ (US)

(72) Inventor: Lei Zou, Oslo (NO)

(21) Appl. No.: 18/306,117

(22) Filed: Apr. 24, 2023

Related U.S. Application Data
(63) Continuation of application No. 63/363,695, filed on Apr. 27, 2022.

(51) Int. Cl. H03F 3/45; H03F 1/48

(52) U.S. Cl. CPC H03F 3/45475; H03F 3/45273; H03F 1/486

(57) ABSTRACT

One or more examples relate to inverting current amplification and related touch systems. An apparatus includes a first transistor, a second transistor, and a feedback loop. The first transistor and the second transistor provide controlled current at the second transistor that is a copy of current at the first transistor when respective drain-source voltages of the first transistor and the second transistor are substantially equal. The feedback loop sets respective drain-source voltages of the first transistor and the second transistor to be substantially equal, wherein a responsiveness of the feedback loop is proportional to a set transconductance of the feedback loop.

### CROSS-REFERENCE TO RELATED APPLICATIONS

This application claims the benefit under 35 U.S.C. § 119(e) of the priority date of U.S. Provisional Patent Application Ser. No. 63/363,695 Apr. 27, 2022, for CURRENT AMPLIFICATION AND TOUCH CONTROLLER INCLUDING THE SAME, the contents and disclosure of which is incorporated herein in its entirety by this reference.

### FIELD

One or more examples relate to inverting current amplification. One or more examples relate to differential current amplification utilizing inverting current amplification. One or more examples relate to measuring capacitance of electrodes utilizing differential current amplification and inverting current amplification. One or more examples relate to touch sensing.

### BACKGROUND

Inverting current amplifiers and differential current amplifiers are utilized in a variety of operational contexts, including, but not limited to, capacitance measurements and touch sensing.

### BRIEF DESCRIPTION OF THE DRAWINGS

To easily identify the discussion of any particular element or act, the most significant digit or digits in a reference number refer to the figure number in which that element is first introduced.

FIG. 1 is a schematic diagram of an inverting current amplifier, in accordance with one or more examples.

FIG. 2 is a schematic diagram depicting an inverting current amplifier portion that corresponds to top stage of the inverting current amplifier of FIG. 1.

FIG. 3 is a flow-diagram depicting a process of inverting a current signal, in accordance with one or more examples.

FIG. 4 and FIG. 5 are block diagrams depicting an apparatus that cancels a baseline charge signal received from a measurement charge signal received from a touch electrode, in accordance with one or more examples.

FIG. 6 is a flow-diagram depicting a process to set the bandwidth of an OTA of a feedback loop utilized in the inverting current amplifier of FIG. 1, in accordance with one or more examples.

FIG. 7 is a flow-diagram depicting a process to set the bandwidth of an OTA of a feedback loop utilized in the inverting current amplifier of FIG. 1, in accordance with one or more examples.

FIG. 8 is a flow-diagram depicting a process to determine a state of an electrode of a capacitive sensor that includes cancelling a baseline charge signal from a measurement charge signal, in accordance with one or more examples.

FIG. 9 is a block-diagram depicting a system to sense touch via capacitance, in accordance with one or more examples.

### DETAILED DESCRIPTION

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, steps, features, functions, or the like.

It will be readily understood that the components of the examples as generally described herein and illustrated in the drawing could be arranged and designed in a wide variety of different configurations. Thus, the following description of various examples is not intended to limit the scope of the present disclosure, but is merely representative of various examples. While the various aspects of the examples may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the examples disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer is configured to execute computing instructions (e.g., software code) related to examples of the present disclosure.

The examples may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, any relational term, such as “over,” “under,” “on,” “underlying,” “upper,” “lower,” etc., is used for clarity and convenience in understanding the disclosure and accompanying drawings and does not connote or depend on any specific preference, orientation, or order, except where the context clearly indicates otherwise.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The terms “on” and “connected” may be used in this description interchangeably with the term “coupled,” and have the same meaning unless expressly indicated otherwise or the context would indicate otherwise to a person having ordinary skill in the art.

Capacitance of an electrode of a touch sensor may be utilized by a touch controller to detect a change in the state of the electrode or touch sensor more generally. Non-limiting examples of detectable states include: presence of an object spaced apart from the electrode but not physically contacting the electrode or a material in contact with the electrode (also called “hover”), presence of an object in physical contact with the electrode or a material in capacitive contact with the electrode (also called “touch”), or no object present (also called “no touch”). Some touch controllers do not discriminate between hover and touch or hover and no touch.

Some touch sensing systems determine capacitance of an electrode utilizing the amount of charge transferred between the electrode and a measurement circuit. The rate of charge transferred between the electrode and the measurement circuit changes in response to changes in capacitance of the electrode, and capacitance of the electrode changes in response to presence of an object, thus, the rate of charge transfer, or amount of charge transferred during a predetermined time duration, is indicative of the presence of an object—e.g., “touch” or “no touch.”

The portion of determined capacitance (e.g., via self-capacitance measurement, without limitation) of an electrode attributable to the electrode and coupled circuit of a touch sensor (or touch sensor and host device that includes the touch sensor), is referred to as the “baseline capacitance” or “baseline cap,” and the amount of charge transferred attributable to the electrode and coupled circuit of the touch sensor, is referred to as the “baseline capacitance charge” or “baseline cap Q.” Generally speaking, the baseline cap is the determined capacitance of an electrode when no object is present, and the baseline cap Q is the determined amount of charge transferred when no object is present.

The portion of the determined capacitance (e.g., via self-capacitance measurement, without limitation) of an electrode attributable to the presence of an object other than the touch sensor (or the touch sensor and host device that includes the touch sensor), is referred to as the “projected capacitance” or “projected cap,” and the amount of charge transferred attributable to the presence of an object other than the touch sensor (or touch sensor and host device that includes the touch sensor), is referred to as the “projected capacitance charge” or “projected cap Q.” Generally speaking, the projected cap is the determined capacitance of an electrode when an object is present less the baseline capacitance, and the projected cap Q is the determined amount of charge transferred when an object is present less the baseline cap Q.

Generally speaking, the total determined capacitance of an electrode is equal to the sum of the baseline capacitance and the projected capacitance, and the total determined amount of charge transferred is equal to the sum of the baseline cap Q and the projected cap Q. The total determined capacitance of the electrode is referred to as the “measurement capacitance” of the electrode and the total amount of charge transferred (e.g., an input current) is referred to as the “measurement capacitance charge” or “measurement cap Q.” Information about the measurement capacitance of the electrode is referred to as the “measurement signal,” and information about the measurement capacitance charge is referred to as a “measurement charge signal.” A measurement charge signal may be utilized to represent or determine a measurement signal.

The information in a measurement signal about the baseline cap is referred to herein as the “baseline signal,” and the information in a measurement charge signal about the baseline capacitance charge (baseline cap Q) is referred to herein as the “baseline charge signal” or “baseline Q signal.” The information in a measurement signal about the projected cap is referred to herein as the “touch signal,” and the information in a measurement charge signal about the projected capacitance charge (projected cap Q) is referred to herein as the “touch charge signal” or “touch Q signal.” A baseline charge signal may be utilized to represent or determine a baseline signal. A touch charge signal may be utilized to represent or determine a touch signal.

A touch controller's “sensitivity” refers to the magnitude of change in a touch signal, and accordingly, the magnitude of change in a touch charge signal, that may be detected by the touch controller. Increasing a touch controller's sensitivity means the touch controller can detect smaller changes in a touch signal than before the sensitivity was increased. Decreasing a touch controller's sensitivity means the touch controller can detect only larger changes in a touch signal than before the sensitivity was decreased.

When an object (e.g., a finger, hand or stylus, without limitation) hovers above a touch screen (i.e., spaced (e.g., by an air gap, without limitation) some distance from a touch electrode of a touch screen, at least momentarily), the touch signal is smaller (e.g., orders of magnitude smaller, without limitation) than the baseline signal.

One approach is to reduce or cancel the baseline signal from a measurement signal to reduce or eliminate the influence of the baseline capacitance on the measurement signal. The baseline signal is inverted (i.e., gain of −1) and the inverted baseline signal combined with the measurement signal to cancel the baseline signal from the measurement signal.

An inverting current amplifier may be used to invert the baseline signal, however, as discussed below, some inverting current amplifiers that use cascode current mirrors exhibit an imperfect inverse gain (i.e., realizes an inverse gain that is different than −1) at least when used for touch sensing. So, a baseline signal may not reliably be completely cancelled (or reduced to a negligible magnitude) based solely on an output of such an inverting current amplifier. Such an un-cancelled portion of the baseline cap signal is referred to herein as an “offset signal,” and the charge of an offset signal is referred to herein as “offset Q.” The offset signal can be so large as to corrupt a touch detection if it is included with a touch signal, and lead to inadvertent detection of a “touch” state—i.e., such inadvertent detection being a touch error.

If an input signal received at a measurement circuit includes the touch signal and the offset signal, then the measurement circuit may experience a touch error. Touch sensing systems known to the inventor of this disclosure that reduce or cancel the baseline signal from the measurement signal apply some further gain to the touch signal to account for the offset signal, so that the touch signal may be measured.

If the baseline signal were cancelled such that the touch signal can be used directly by the touch measurement circuit, or is the only signal that has to be amplified, and the operating (e.g., input range, without limitation) range of the touch measurement circuit may correspond to the touch signal, which is typically a smaller single than a baseline signal.

Some inverting current amplifiers utilize cascode current mirrors. A cascode current mirror is sensitive to voltage spikes caused by transient current injected at an input of the inverting current amplifier, which causes inaccurate current gain (i.e., gain of the inverting current amplifier is not −1). A cascode current mirror requires sufficient voltage headroom to exhibit accurate current gain, but voltage spikes shrink the voltage headroom of a cascode current mirror such that the voltage headroom is insufficient for the cascode current mirror, and an inverting current amplifier including the same may therefore operate in an unpredictable manner. The inventor of this disclosure appreciates that such voltage spikes can cause the drain-source voltages (Vds) of primary and secondary transistors in a cascode current mirror to diverge, at least momentarily, and sufficiently divergent drain-source voltages cause inaccurate current mirroring. The inventor of this disclosure appreciates that increasing responsiveness of the current mirror of the inverting current amplifier to reduce or eliminate the divergent drain-source voltages would increase accuracy of current mirroring and gain of an inverting current amplifier.

The inventor of this disclosure appreciates that an inverting current amplifier that exhibits accurate current gain of substantially −1 (i.e., 99% or better accuracy) could be used to completely cancel (i.e., cancel 99% or more) the baseline cap Q in an input current.

One or more examples relate, generally, to a structure of an inverting current amplifier. The structure is less sensitive (i.e., than one using a typical cascaded current mirror), to voltage spikes caused by transient current injected at an input of the inverting current amplifier, and thus less susceptible to providing an inaccurate current gain due to such transient current. Example inverting current amplifiers discussed herein may realize an inverting gain of substantially −1 (i.e., with 99%% or better accuracy).

One or more examples relate, generally, to a set of differential current amplifiers that respectively include an example inverting current amplifier discussed herein. The differential current amplifiers amplify respective input currents and combine the amplified input currents, invert their respective amplified input currents utilizing their respective example inverting current amplifiers discussed herein, and combine their respective amplified input currents with the respective inverted amplified input currents generated by the other differential current amplifier of the set. In one or more examples, the differential current amplifiers of the set are neighboring differential amplifiers (i.e., handling input currents from sensor lines that are physically located directly adjacent to each other). In one or more examples, neighboring differential current amplifiers may, or may not, be physically located directly adjacent to each other.

One or more examples relate, generally, to a touch controller or touch sensing system that includes at least one example set of differential current amplifiers discussed herein to respectively receive input signals generated in response to a touch measurement process from touch electrodes (i.e., two different touch electrodes). The respective example inverting current amplifiers discussed herein of the set of differential current amplifiers are utilized to generate a −baseline cap Q (i.e., an inverted baseline cap Q), or more generally, a −baseline signal (i.e., an inverted baseline signal). The −baseline signal is utilized to cancel (e.g., entirely cancel or cancel so that only a negligible amount remains that can be ignored, without limitation) the baseline signal present in at least one of the input signals. In one or more examples, an offset signal is therefore not present (e.g., completely not present or negligibly present such that it can be ignored, without limitation) in the signal provided to the measurement circuit of the touch controller. In the case of the differential current amplifier that cancels baseline Q signal, only the touch Q signal or some multiple thereof that was present in the input current received from an electrode, or touch sensor more generally, is present in an output current of the differential current amplifier.

In one or more examples, the amount of touch Q signal in the output current provided by an example differential amplifier discussed herein may have a predetermined relationship (e.g., a ratio or multiple, without limitation) to the amount of touch Q signal present in the input current received by the differential amplifier. To differentiate herein, the amount of touch Q signal present in the input current may be referred to herein as “input touch Q signal,” and the amount of touch Q signal in the output current may be referred to herein as “output touch Q signal.”

Since the output current of the differential amplifier only includes the touch Q signal, it may be processed (e.g., by a touch measurement circuit, without limitation) without gain or without high gain. The touch controller may exhibit high sensitivity to changes in the touch Q signal (in the case of both input and output touch Q signals). An example inverting current amplifier and differential amplifiers including the same, may increase sensitivity of a touch measurement circuit or a touch controller including the same, as compared to known current amplifiers that implement similar gain.

One or more examples of differential structures discussed herein may find, as a non-limiting example, application in touch sensing systems where hover detection is desired.

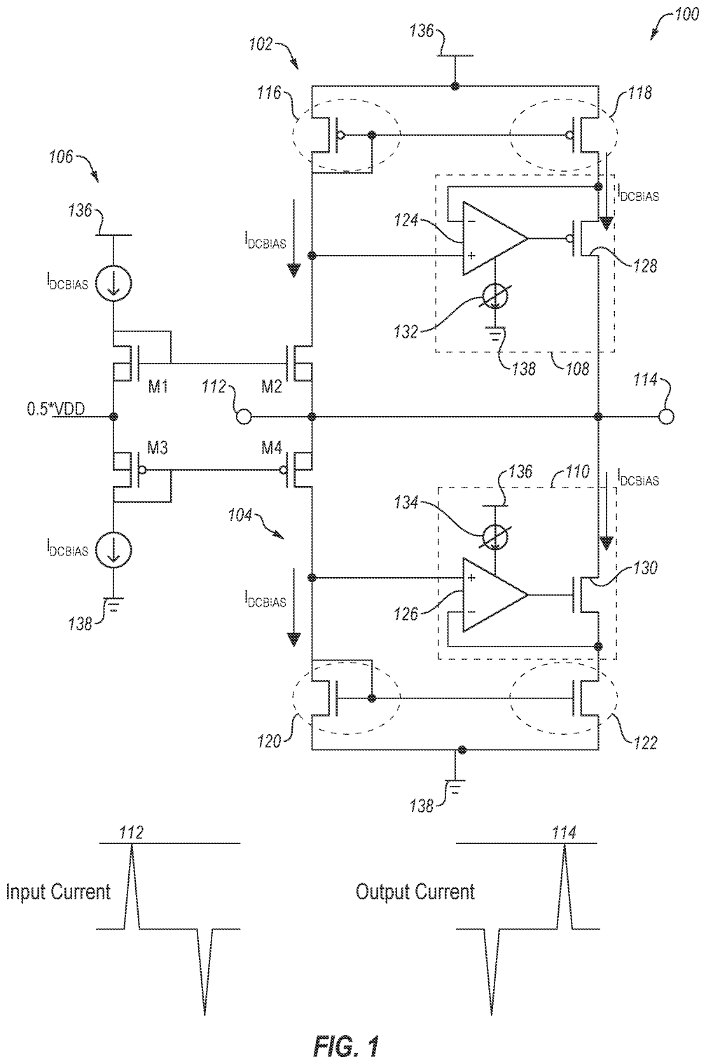

FIG. 1 is a schematic diagram of an inverting current amplifier 100, in accordance with one or more examples. Inverting current amplifier 100 exhibits no, or negligible, error in the output touch Q signal.

Inverting current amplifier 100 includes input terminal 112, output terminal 114, top stage 102, bottom stage 104, and translinear loop 106.

Translinear loop 106 (i.e., the arrangement of transistors M1, M2, M3, M4 depicted by FIG. 1) provides DC bias currents (I_{DCBIAS}) to primary transistor 116, 120.

NMOS transistors M1 and M2 are sized the same, and PMOS transistors M3 and M4 are sized the same. Respective gates are coupled to respective drains of NMOS transistor M1 and PMOS transistor M2. The gate of NMOS transistor M2 is coupled to the gate of NMOS transistor M1, and thus to the drain of NMOS transistor M1. The gate of PMOS transistor M4 is coupled to the gate of PMOS transistor M3, and thus to the drain of PMOS transistor M3.

The DC bias currents (I_{DCBIAS}) are represented in FIG. 1 by two DC current sources: a first DC current source is coupled to a drain of NMOS transistor M1 and points from VDD to 0.5 VDD via NMOS transistor M1, and a second DC current source is coupled to a drain of PMOS transistor M3 and points from 0.5 VDD to ground via PMOS transistor M3.

The respective DC bias currents provided by the first DC current source and the second DC current source are equal. The DC current mirrored at transistor M2 is the bias current of primary transistor 116, and the DC current mirrored at transistor M4 is the bias current of primary transistor 120.

The drain-source current of NMOS transistor M1 is set to the DC bias current provided by the first DC current source, thus, the drain-source current at NMOS transistor M2, which is a copy of the drain-source current at NMOS transistor M1, is set equal to the DC bias current. Further, the drain-source current at primary transistor 116, which is in series with NMOS transistor M2, is set equal to the DC bias current.

The drain-source current of PMOS transistor M3 is set to the DC bias current provided by the second DC current source, thus, the drain-source current at PMOS transistor M4, which is a copy of the drain-source current at PMOS transistor M3, is set equal to the DC bias current. Further, the drain-source current at primary transistor 120, which is in series with PMOS transistor M4, is set equal to the DC bias current.

In the bidirectional inverting current amplifier depicted by FIG. 1, the DC bias currents enable both top current mirror 102 and bottom current mirror 104 to operate. A contemplated transient current is bidirectional. In the case of an injection of a transient current to input terminal 112, it can be mirrored either by top current mirror 102 or bottom current mirror 104, and then provided to the output terminal 114 as an output current that is an inverted version of the input transient current.

The node between NMOS transistor M1 and PMOS transistor M3 is set by an external voltage source (voltage source not depicted) to one-half (½) the voltage of second supply voltage 138 (0.5 VDD). The gate and drain of NMOS transistor M1 are set to 0.5 VDD plus the gate-source voltage Vgs of NMOS transistor M1. The gate and drain of PMOS transistor M3 are set to 0.5 VDD minus the gate-source voltage Vgs of PMOS transistor M3.

When NMOS transistor M2 is the same as NMOS transistor M1, PMOS transistor M4 is the same as PMOS transistor M3, the drain-source current of NMOS transistor M2 is equal to a drain-source current of NMOS transistor M1, and the drain-source current of PMOS transistor M4 is equal to the drain-source current of PMOS transistor M3, then the gate-source voltage Vgs of NMOS transistor M1 is equal to the gate-source voltage Vgs of NMOS transistor M2 and the gate-source voltage Vgs of PMOS transistor M3 is equal to the gate-source voltage Vgs of PMOS transistor M4. So, the source voltage of NMOS transistor M2 and the source voltage of PMOS transistor M4 are both set equal to 0.5 VDD.

Top stage 102 and bottom stage 104 are current mirrors that respectively support unidirectional current output, albeit in opposite directions. Inverting current amplifier 100 includes both top stage 102 and bottom stage 104 to support bi-directional transient current input and output.

Top stage 102 may also be referred to herein as “top current mirror 102” and bottom stage 104 may also be referred to herein as “bottom current mirror 104.” Top stage 102 provides a gain of substantially −1 during current output in a first direction, and bottom stage 104 provides a gain of substantially −1 during current output in a second direction, different than the first direction, since an increased transient input current into inverting current amplifier 100 results in an increase current drawn from output terminal 114.

Top stage 102 includes the primary transistor 116 (also referred to as “first transistor 116”), a secondary transistor 118 (also referred to as “second transistor 118”), and a feedback loop 108 (also referred to as “top feedback loop 108”). Primary transistor 116, secondary transistor 118, and feedback loop 108 of top stage 102 provide a controlled current at secondary transistor 118 that is an inverted copy of current at primary transistor 116, as discussed below. Primary transistor 116 and secondary transistor 118 are p-type metal-oxide-semiconductor field-effect transistors (PMOS).

Bottom stage 104 includes the primary transistor 120 (also referred to as “further first transistor 120”), a secondary transistor 122 (also referred to as “further second transistor 122”), and a feedback loop 110 (also referred to as “bottom feedback loop 110”). Primary transistor 120, secondary transistor 122, and feedback loop 110 of bottom stage 104 of bottom stage 104 provide a controlled current at secondary transistor 122 that is an inverted copy of current at primary transistor 120, as discussed below. Primary transistor 120 and secondary transistor 122 are n-type metal-oxide-semiconductor field-effect transistors (NMOS).

Generally speaking, when respective drain-source voltages Vds of primary transistor 116, 120 and secondary transistor 118, 122 are equal, a controlled current at secondary transistor 118, 122 is copy of current at primary transistor 116, 120 (the controlled current generated at secondary transistor 118 may also be referred to as a “copy current”).

When respective drain-source voltages Vds of primary transistor 116, 120 and secondary transistor 118, 122 are not equal, a current at secondary transistor 118 is not an copy of current at primary transistor 116.

In one or more examples, the ability of inverting current amplifier 100 to accurately mirror a sharp transient current from input terminal 112 to output terminal 114 with substantially (99% or better) accurate gain of −1, is at least partially based on how fast respective drain-source voltages Vds of primary transistor 116, 120 and the associated secondary transistor 118, 122 are set equal by feedback loop 108, 110, as discussed below.

Respective sources of primary transistor 116 and secondary transistor 118 are coupled to a first supply voltage, and respective sources of primary transistor 120 and secondary transistor 122 are coupled to a second supply voltage. The first supply voltage 136 and second supply voltage 138 are different. In one example the first supply voltage is Vdd, and the second supply voltage is a common return, e.g., ground, without limitation. When feedback loop 108 sets a voltage level at a drain of secondary transistor 118 to be equal to a voltage level at a drain of primary transistor 116, then respective drain-source voltages Vds of primary transistor 116 and secondary transistor 118 are equal. Similarly, when feedback loop 108 sets a voltage level at a drain of secondary transistor 122 to be equal to a voltage level at a drain of primary transistor 120, then respective drain-source voltages Vds of primary transistor 120 and secondary transistor 122 are equal. The primary transistor 116, 120 stays in saturation due to the gate being coupled to the drain; Vgs of 116 equals Vds of 116 so that 116 is in saturation. same to 120.

When respective drain-source voltages Vds of primary transistor 116, 120 and the associated secondary transistor 118, 122 are equal, as primary transistor 116, 120 stays in saturation, then associated secondary transistor 118, 122 also stays in saturation due to obtaining the same drain-source voltage Vds.

As mentioned, above, the ability of inverting current amplifier 100 to accurately mirror a sharp transient current from input terminal 112 to output terminal 114 with substantially (99% or better) accurate gain of −1, is at least partially based on how fast respective drain-source voltages Vds of primary transistor 116, 120 and the associated secondary transistor 118, 122 are set equal by feedback loop 108, 110. When feedback loop 108, 110 sets drain-source voltage Vds of secondary transistor 118, 122 equal to drain-source voltage Vds of the primary transistor 116, 120 in a short time duration, the top current mirror 102 and bottom current mirror 104 mirror a sharp transient current from input terminal 112 to output terminal 114 with substantially (99% or better) accurate gain of −1.

Feedback loop 108, 110 includes pass transistor 128, 130, operational transconductance amplifier (OTA) 124, 126, and controlled current source 132, 134.

Feedback loop 108, 110 sets the drain-source voltage Vds of secondary transistor 118, 122 at least partially responsive to a relationship between voltages at respective drains of primary transistor 116, 120 and secondary transistor 118, 122. In one or more examples, the relationship is a difference between voltages at respective drains of primary transistor 116, 120 and secondary transistor 118, 122.

The time duration to set drain-source voltage Vds of secondary transistor 118, 122 equal to drain-source voltage Vds of the primary transistor 116, 120 is determined by feedback loop 108, 110 as discussed below. The specific time duration implemented is a matter of design choice, and may be set, as a non-limiting example, based on specific operating conditions.

Turning to feedback loop 108 of top stage 102, an inverting input of OTA 124 is coupled to the drain of secondary transistor 118. A non-inverting input of OTA 124 is coupled to the drain of primary transistor 116. Alternatively, an non-inverting input of OTA 124 may be coupled to the drain of the primary transistor 116, and a inverting input of OTA 124 may be coupled to the drain of secondary transistor 118.

A bias input of OTA 124 is coupled to second supply voltage 138 via controlled current source 132. An output of OTA 124 is coupled to a gate of pass transistor 128. Pass transistor 128 is coupled between secondary transistor 118 and output terminal 114 of inverting current amplifier 100. A source of pass transistor 128 is coupled to the drain of secondary transistor 118, and a drain of pass transistor 128 is coupled to output terminal 114. In one or more examples, controlled current source 132 may be set to provide a current at a magnitude proportional to a set value (which set value may also be referred to as a “control signal”). As discussed, below, the magnitude of a current at the bias input of OTA 124 may be utilized to set the transconductance of OTA 124 (a “set transconductance”), which sets the bandwidth of OTA 124.

Turning to feedback loop 110 of bottom stage 104, an inverting input of OTA 126 is coupled to a drain of secondary transistor 122. A non-inverting input of OTA 126 is coupled to a drain of primary transistor 120. Alternatively, an non-inverting input of OTA 126 may be coupled to the drain of the primary transistor 120, and a inverting input of OTA 126 may be coupled to the drain of secondary transistor 122.

A bias input of OTA 126 is coupled to first supply voltage 136 via controlled current source 134. An output of OTA 126 is coupled to a gate of pass transistor 130. Pass transistor 130 is coupled between secondary transistor 122 and output terminal 114 of inverting current amplifier 100. A source of pass transistor 130 is coupled to the drain of secondary transistor 122, and a drain of pass transistor 130 is coupled to output terminal 114.

In one or more examples, controlled current source 134 may be set to provide a current at a magnitude proportional to a set value (which set value may also be referred to as a “control signal”). As discussed, below, the magnitude of a current at the bias input of OTA 126 may be utilized to set the transconductance of OTA 126 (a “set transconductance”), which sets the bandwidth of OTA 126.

Generally speaking, a smaller magnitude current at the bias input of OTA 124, 126 results in a smaller transconductance and a smaller bandwidth, as well as a current saving. A larger magnitude current at the bias input of OTA 124, 126 results in a larger transconductance and a larger bandwidth, but at a greater current cost.

In one or more examples, the voltage supplies that provide first supply voltage 136 and second supply voltage 138 are different. First supply voltage 136 sets voltages at respective sources of primary transistor 116 and secondary transistor 118 to the same voltage level, and sets the direction of the current generated by controlled current source 134. Second supply voltage 138 sets voltages at respective sources of primary transistor 120 and secondary transistor 122 to the same voltage level, and sets the direction of the current generated by controlled current source 132. In the specific non-limiting example depicted by FIG. 1, the voltage supply that provides second supply voltage 138 is a zero or ground voltage supply, and the voltage supply that provides first supply voltage 136 is a non-zero voltage supply.

Generally speaking, OTA 124, 126 is a voltage controlled current source that generates an output current at least partially responsive to a differential input voltage received at its inverting and non-inverting inputs. An output of OTA 124, 126 provides a current to a gate of pass transistor 128, 130 and current charging or discharging the gate cap of the pass transistor to convert to gate voltage.

The magnitude of the gate voltage at pass transistor 128, 130 affects conduction of pass transistor 128 130, which means the voltage level at source of pass transistor 128, 130 can be changed via the magnitude of the gate voltage. For PMOS pass transistor 128, increasing gate voltage decreases conductance, decreasing gate voltage increases conductance. For PMOS pass transistor 128, a higher gate voltage sets a lower conductance than a lower gate voltage. For NMOS pass transistor 130, increasing gate voltage increases conductance, and decreasing gate voltage decreases conductance. For NMOS pass transistor 130, a lower gate voltage sets a lower conductance than a higher gate voltage. Turning to control of the drain-source voltages of primary transistor 116, 120 and secondary transistor 118, 122, when the respective voltages at the inverting and non-inverting inputs of OTA 124, 126 are different (this is an abrupt voltage different generation from the fast transient currents or voltage spikes voltage spike at 112), OTA 124, 126 increases or decreases its output current, which changes the gate voltage of pass transistor 128, 130, which changes the voltage level at the source of pass transistor 128, 130, which changes the drain voltage of secondary transistor 118, 122. OTA 124, 126 receives the changed drain voltage of secondary transistor 118, 122 and continues to increase or decrease its output current until the drain voltage of primary transistor 116, 120 is equal to the drain voltage of secondary transistor 118, 122. OTA 124, 126 stops changing its output current when the drain voltage of primary transistor 116, 120 is equal to the drain voltage of secondary transistor 118, 122.

The non-inverting input of OTA 124 monitors the drain voltage of primary transistor 116, the inverting input of OTA 124 monitors the drain voltage of secondary transistor 118, the non-inverting input of OTA 126 monitors the source voltage of primary transistor 120, and the inverting input of OTA 126 monitors the source voltage of secondary transistor 122, as discussed below.

Generally speaking, the time duration for feedback loop 108, 110 set the drain voltage of secondary transistor 118, 122 via OTA 124, 126 in response to a voltage difference between inverting/non-inverting inputs of OTA 124, 126 is referred to herein as the “responsiveness” of the feedback loop 108, 110.

The “unity gain bandwidth” (or just “bandwidth”) of OTA 124, 126 is the range of frequencies at which OTA 124, 126 can accurately amplify a signal, which may also be characterized as the frequency at which the gain drops below a threshold. The unity gain bandwidth may be expressed as a range of frequencies, also referred to as the “width.” In the case of an abrupt change in voltage difference at the inputs of OTA 124, 126 if the frequency of the input voltage signal is not within the unity gain bandwidth of OTA 124, 126, then OTA 124, 126 may generate an incorrect or unpredictable output current in respect to input voltage signal.

The “transconductance” of OTA 124, 126 is a characterization of ability to convert an input voltage signal to an output current signal. The transconductance of OTA 124, 126 is at least partially based on the transconductance of the input transistors of OTA 124, 126 (input transistors not depicted), which transconductance are set by the magnitude of the current at a bias input of OTA 124, 126. Unity gain bandwidth of OTA 124, 126 may be expressed as the transconductance of the input transistors of OTA 124, 126 divided by the gate capacitance of the pass transistor 128, 130, or Unity Gain Bandwidth=Gm/Cload, where Gm is the input transistor transconductance, Cload is the load of the OTA, which, in FIG. 1, is the gate capacitor of the pass transistor. Generally speaking, the higher the transconductance of OTA 124, 126, the wider the unity gain bandwidth of OTA 124, 126.

The transconductance of OTA 124, 126 is at least partially based on a magnitude of current received at a bias input of OTA 124, 126. The current received at the bias input of OTA 124, 126 is utilized to bias an input stage (e.g., an input differential pair of transistors (e.g., bipolar junction transistors (BJTs)) or metal-oxide-semiconductor-field-effect transistors (MOSFETs, without limitation), without limitation) of OTA 124, 126. Generally speaking, the higher the bias current, the larger the transconductance, the larger the unity gain bandwidth, and the wider the bandwidth.

The transconductance of OTA 124, 126 changes in response to changes in the magnitude of current received at the bias input of OTA 124, 126. So, a transconductance of OTA 124, 126 may be set via a current at the bias input of OTA 124, OTA 126, and thus a bandwidth of OTA 124, OTA 126 may be set via the current at the bias input of OTA 124, 126. As discussed below, the current at a bias input of OTA 124, 126 of inverting current amplifier 100 may be set by controlled current source 132, 134, and so may be changed by setting the magnitude (i.e., amplitude) of current generated by controlled current source 132, 134.

Controlled current source 132, 134 may be utilized to tune or set the bandwidth of OTA 124, 126. Controlled current source 132, 134 may also be referred to herein as a “tuning current source 132, 134” when tuning a bandwidth of OTA 124, 126, or a “controlling current source 132, 134” when setting a bandwidth of OTA 124, 126 (e.g., setting transconductance to a predetermined value corresponding to desired transconductance/bandwidth, without limitation). Increasing the magnitude of current generated by controlled current source 132, 134 increases the bandwidth of the OTA 124, 126 to be higher, and decreasing the current amplitude of current generated by controlled current source 132, 134 decreases the bandwidth of the OTA 124, 126 to be lower.

Controlled current source 132, 134 supports a wide tuning bandwidth of OTA 124, OTA 126 vs input transient current amplitude at input terminal 112: a large input transient current amplitude calls for large bandwidth, a small input transient current amplitude calls for small bandwidth.

A voltage at the non-inverting input of OTA 124, 126 is forced to be equal to a voltage at an inverting input of OTA 124, 126 by the feedback loop that includes the gates of pass transistor 128, 130. The faster (in terms of time) the voltages at the inverting and non-inverting inputs of OTA 124, 126 are set equal, the faster (in terms of time) the drain-source voltages Vds of primary transistor 116, 120, and secondary transistor 118, 122 are set equal, and the more accurately top stage 102, bottom stage 104, or inverting current amplifier 100, more generally, provides an output current with a gain of −1.

Accordingly, the accuracy of inverting current amplifier 100 is proportional to the responsiveness of the feedback loops that include OTA 124, 126 (or more generally the responsiveness of the feedback loop 108, 110 that includes OTA 124, 126). A transient signal exhibits a sharp change in amplitude in a short time duration, and the change in amplitude can be tracked by a suitably responsive feedback loop. The responsiveness of the feedback loop is set by the unity gain bandwidth of OTA 124, 126, accordingly, as discussed above, controlled current source 132, 134 controls the transconductance of OTA 124, 126, which controls the bandwidth of OTA 124, 126, which controls the responsiveness of the feedback loops that include OTA 124, 126 and thus the responsiveness of feedback loop 108, 110.

The relationship between drain-source current Ids and gate-source voltage Vgs may be expressed as: Ids=k*(Vgs−Vth)\hat{ }2(1+λ*Vds), where k is the transconductance parameter, λ is the channel modulation parameter, Vds is the drain-source voltage, Vgs is the gate-source voltage, and Vth is the threshold voltage for a transistor to turn ON or turn OFF. The expression for drain-source current Ids is included, here, to illustrate, mathematically, that if Vds is not equal at primary transistor 116, 120 and secondary transistor 118, 122 then respective drain-source currents Ids will be different, and so not properly mirrored.

Once the bandwidth of OTA 124, 126 is set, it can accommodate a transient current at input terminal 112 that corresponds to the set bandwidth. The time duration of a transient current is proportional to the baseline capacitance of a touch screen. A large touch screen with large baseline capacitance experiences fast transient current and can cause a fast transient current at input terminal 112. A small touch screen with small baseline capacitance experiences slower transient current and can cause a slower transient current at input terminal 112. In one or more examples, the bandwidth of OTA 124, 126 may be set at least partially based on size (dimensions) of a touch screen or capacitance of a touch screen for which it will be used. For example, the bandwidth of OTA 124 may set proportional to touch screen size, i.e., as touch screen size increases the set bandwidth of OTA 124 may increase. Additionally or alternatively to dimension, in one or more examples, the bandwidth of OTA 124, 126 may be tuned for a specific touch screen or class of touch screen.

In one or more examples, bandwidth of OTA 124, 126 may be set according to a coarse setup process and a fine setup process, as a non-limiting example, according to a touch screen, or class of touch screen, to be utilized. In one or more examples, fine selection of bandwidth of OTA 124, 126 may be set according to a real-time test procedure, e.g., by sweeping the tuning controlled current source 132, 134 with one or more small steps in current amplitude until an acceptable bandwidth is obtained, without limitation.

In one or more examples, the bandwidth of OTA 124, OTA 126 may be tuned or pre-set, as the case may be, to a bandwidth that is smaller than the largest available bandwidth at OTA 124, OTA 126, as a non-limiting example, to save power or current.

Notably, inverting current amplifier 100 is not limited to applications where fast transient currents injected at the input nor voltage spikes caused by the same are expected or possible. Inverting current amplifier 100 may be utilized in applications where fast transient currents or voltage spikes are not expected, which is specifically contemplated. Broad applicability is a non-limiting example of an advantage of inverting current amplifiers in accordance with one or more examples discussed herein.

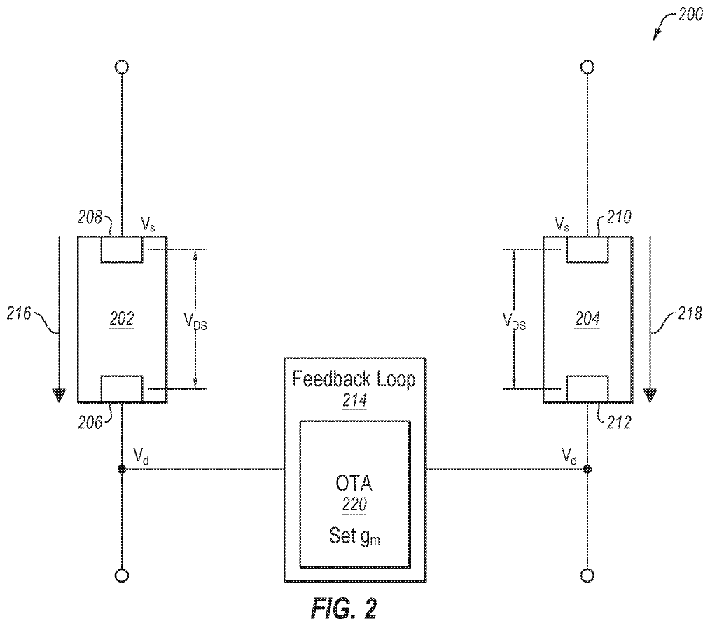

FIG. 2 is a schematic diagram depicting inverting current amplifier portion 200 that corresponds to first top stage 102 of inverting current amplifier 100. FIG. 2 depicts some of the voltages and currents discussed above. Inverting current amplifier portion 200 includes first transistor 202, second transistor 204, and feedback loop 214. Feedback loop 214 includes OTA 220 having set transconductance (“set gm”).

Respective source voltages of source 208 of first transistor 202 and source 210 of second transistor 204 are set to voltage Vs, and feedback loop 214 sets respective drain voltages of drain 206 of first transistor 202 and drain 212 of second transistor 204 to a same voltage level Vd. When respective drain-source voltages of first transistor 202 and second transistor 204 are equal (both Vds), controlled current 218 at second transistor 204 is generated that is a copy of current 216 at first transistor 202.

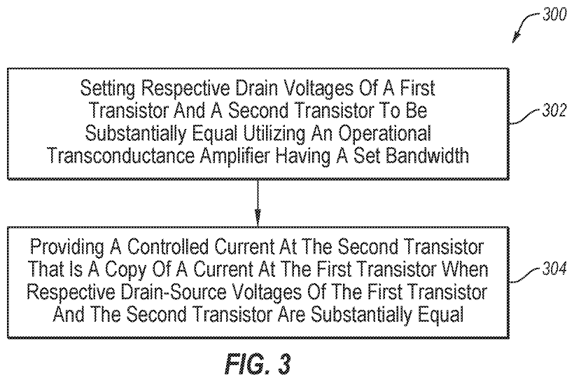

FIG. 3 is a flow-diagram depicting a process 300 to inverting a current signal, in accordance with one or more examples. One or more operations of process 300 may be performed, as a non-limiting example, by inverting current amplifier 100.

Although the example process 300 depicts a particular sequence of operations, the sequence may be altered without departing from the scope of the present disclosure. For example, some of the operations depicted may be performed in parallel or in a different sequence that does not materially affect the function of the process 300. In other examples, different components of an example device or system that implements the process 300 may perform functions at substantially the same time or in a specific sequence.

According to one or more examples, process 300 includes setting respective drain voltages of a first transistor and a second transistor to be substantially equal utilizing an operational transconductance amplifier having a set bandwidth at operation 302.

According to one or more examples, process 300 includes providing a controlled current at the second transistor that is an inverted copy of a current at the first transistor when respective drain-source voltages of the first transistor and the second transistor are substantially equal at operation 304.

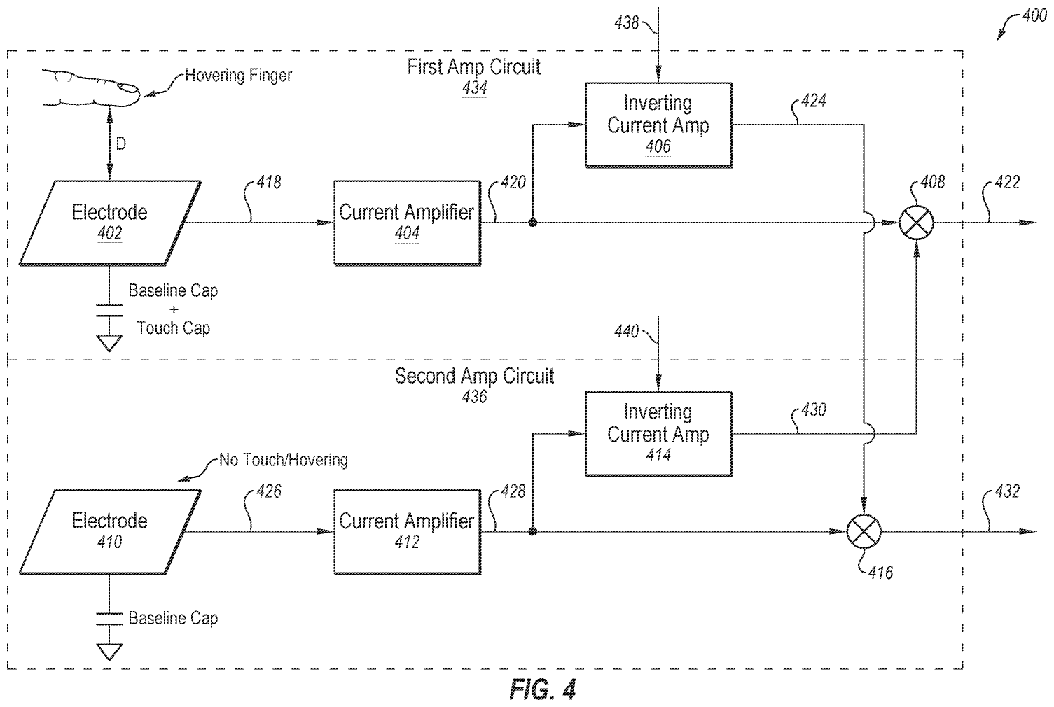

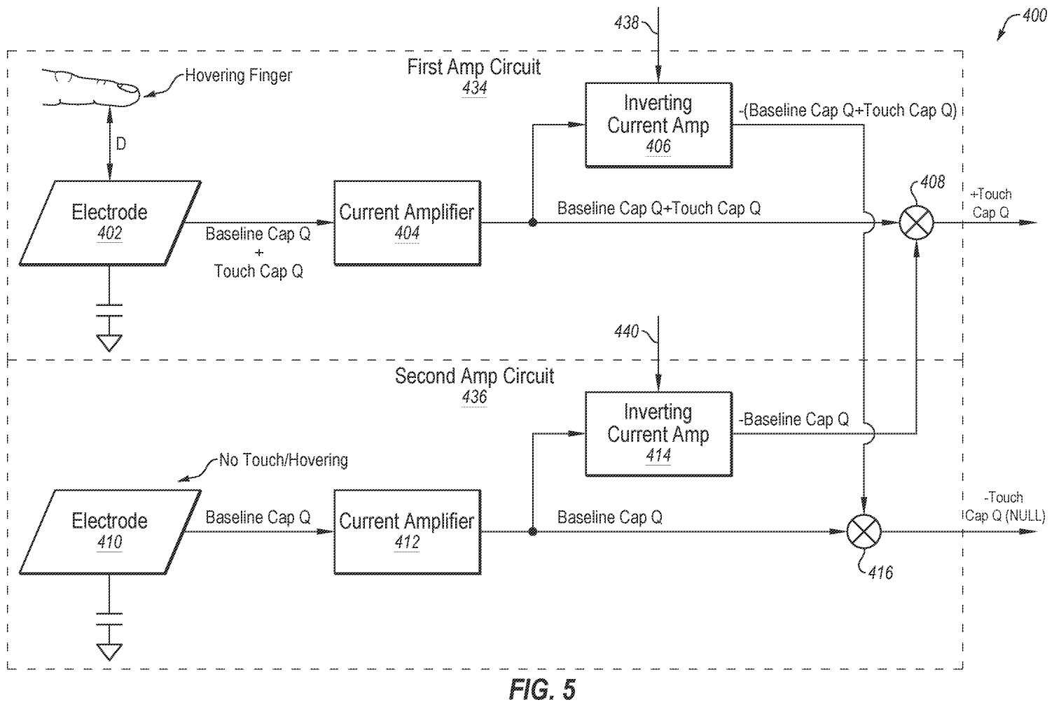

FIG. 4 and FIG. 5 are block diagrams depicting an apparatus 400 that cancels baseline cap Q received from a touch electrode, in accordance with one or more examples. When apparatus 400 is included with a touch sensor, then apparatus 400 may be referred to as “touch sensor portion 400.”

Apparatus 400 includes first amp circuit 434 and second amp circuit 436. First amp circuit 434 includes electrode 402, current amplifier 404, inverting current amp 406, and summer 408. Second amp circuit 436 includes electrode 410, current amplifier 412, inverting current amp 414 and summer 416. Electrode 402 and electrode 410 are depicted in first amp circuit 434 and second amp circuit 436, respectively, for ease of illustration and should be considered optional elements of first amp circuit 434 and second amp circuit 436 as they are coupled to provide input current 418 and input current 426 to first amp circuit 434 and second amp circuit 436, respectively.

When generated in response to a touch measurement process, input current 418 and input current 426 are current signals, and the current may include a component charge that represents a baseline signal (a “first component charge”) and a component charge that represents a touch signal (a “second component charge”).

First amp circuit 434 and second amp circuit 436 are current amplification circuits, and more specifically, current differential amplification circuits. First amp circuit 434 and second amp circuit 436 amplify input current 418 and input current 426, respectively, as discussed below, to generate output current 422 and output current 432, respectively. Respective gains of first amp circuit 434 and second amp circuit 436 may be programmable, and may be set, as a non-limiting example, to generate output current 422 and output current 432 within an operational range of a touch measurement circuit (touch measurement circuit not depicted).

Electrode 402 and electrode 410 exhibits substantially the same baseline cap in response to a capacitive measurement process. When not influenced by an object, electrode 402 and electrode 410 exhibit capacitance equal to baseline cap. When respectively influenced by an object, such as the hovering finger depicted in FIG. 4, without limitation, electrode 402 and electrode 410 exhibit capacitance equal to the sum of baseline cap and projected cap. In the specific example depicted by FIG. 4, electrode 402 exhibits capacitance equal to the sum of baseline cap and projected cap (due to the hovering finger), and electrode 410 exhibits capacitance equal to baseline cap (no hovering finger or other object present).

Turning to second amp circuit 436, when generated in response to a touch measurement process, input current 426 solely includes the baseline Q. So, when generated in response to a touch measurement process, input current 426 is a current signal and it includes a component charge that represents the baseline signal. A component charge that represents the touch signal is equal to zero or is not (not or negligibly) present in input current 426.

Current amplifier 412 amplifies a current signal received at its input (increases the amplitude of a current signal in a predictable manner, or decreases the amplitude of a current signal (in the case of a fractional gain amplifier) in a predictable manner, by adding or subtracting charge) and provides the amplified current signal at its output. Here, current amplifier 412 receives input current 426 and provides amplified input current 428. Baseline Q signal is present in amplified input current 428 in the same proportions it was present in input current 426.

An output of current amplifier 412 is coupled to an input of inverting current amp 414 and to an input of summer 416. A further input of summer 416 is coupled to an output of inverting current amp 406 of first amp circuit 434, discussed below.

Inverting current amp 414 inverts a current signal received at its input and provides the inverted (i.e., reversed in polarity) current signal at its output. In one or more examples, inverting current amps 414 is, or includes, an inverting current amplifier 100 of FIG. 1. Inverting current amp 414 is controlled by control signal 440, which may represent the current generated by a current source (e.g., controlled current source 132, 134, without limitation), or a gain setting that controls the magnitude of a current generated by a current source. In either case, the gain of inverting current amp 414 is set by control signal 440.

Here, inverting current amp 414 receives amplified input current 428 and provides inverted current 430. Inverting amplified input current 428 also inverts (reverses the polarity) of baseline Q signal present in amplified input current 428, such that −baseline Q signal is present in inverted current 430.

The output of inverting current amp 414 is coupled to an input of summer 408. A further input of summer 408 is coupled to an output of current amplifier 404 of first amp circuit 434.

Turning to first amp circuit 434, when generated in response to a touch measurement process, input current 418 includes the baseline Q and the touch Q. So, when generated in response to a touch measurement process, input current 418 is a current signal and it includes a component charge that represents the touch signal and a further component charge that represents the baseline signal.

Current amplifier 404 amplifies a current signal received at its input (increases the amplitude of a current signal in a predictable manner, or decreases the amplitude of a current signal (in the case of a fractional gain amplifier) in a predictable manner, by adding or subtracting charge) and provides the amplified current signal at its output. Here, current amplifier 404 receives input current 418 and provides amplified input current 420. The baseline Q signal and the touch Q signal are present in amplified input current 420 in the same proportions they were present in input current 418.

An output of current amplifier 404 is coupled to an input of inverting current amp 406 and to an input of summer 408. As discussed above, a further input of summer 408 is coupled to an output of inverting current amp 414 of second amp circuit 436.

Inverting current amp 406 inverts a current signal received at its input and provides the inverted (i.e., reversed in polarity) current signal at its output. In one or more examples, inverting current amp 406 is, or includes an inverting current amplifier 100 of FIG. 1. Inverting current amp 406 is controlled by control signal 438, which may represent the current generated by a current source (e.g., controlled current source 132, 134, without limitation), or a gain setting that controls the magnitude of a current generated by a current source. In either case, the gain of inverting current amp 406 is set by control signal 440.

Summer 408 adds current signals received at its inputs, and the sum of the input signals at its output. Here, summer 408 receives inverted current 430, which includes the −baseline Q signal provided by inverting current amp 414, and amplified input current 420, which includes the baseline Q signal and the touch Q signal provided by current amplifier 420. Summer 408 combines (adds) amplified input current 420 and inverted current 430, and since inverted current 430 is of the opposite polarity to amplified input current 420, summer 408 effectively subtracts amplified input current 428 from amplified input current 420. The −baseline Q signal present in inverted current 430 cancels out the baseline Q signal present in amplified input current 420. Thus, output current 422 includes the touch Q signal, but does not include the baseline Q signal.

Similarly, summer 416 combines (adds) inverted current 424 and amplified input current 428. Here, inverted current 424 includes the −baseline Q signal provided by inverting current amp 406, and the amplified input current 428 provided by current amplifier 428 includes the baseline Q signal, which cancel each other. Thus, output current 432 includes the touch Q signal, but does not include the baseline Q signal. Here, it is a negative touch Q signal, which is taken as NULL signal in the measurement system.

Since inverting current amp 406 of first amp circuit 434 and inverting current amp 414 of second amp circuit 436 respectively exhibit a gain of substantially −1 (with 99% or greater accuracy), first amp circuit 434 can cancel baseline Q signal and provide output current 422 that does not include baseline Q signal and substantially only includes touch Q signal.

FIG. 5 depicts apparatus 400 but with the baseline Q and projected Q instead of the current signals depicted in FIG. 4.

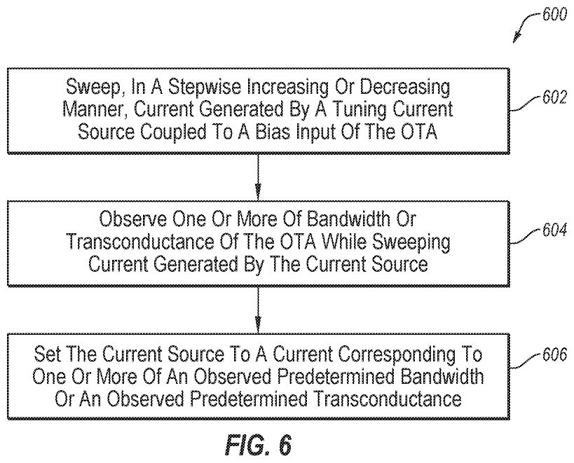

FIG. 6 is a flow-diagram depicting a process 600 to set the bandwidth of an OTA of a feedback loop utilized in an inverting current amplifier 100, in accordance with one or more examples.

Although the example process 600 depicts a particular sequence of operations, the sequence may be altered without departing from the scope of the present disclosure. For example, some of the operations depicted may be performed in parallel or in a different sequence that does not materially affect the function of the process 600. In other examples, different components of an example device or system that implements the process 600 may perform functions at substantially the same time or in a specific sequence.

According to one or more examples, process 600 includes sweeping, in a stepwise increasing or decreasing manner, current generated by a tuning current source coupled to a bias input of the OTA at operation 602. In one or more examples, an amplitude of current generated by the current source is swept in a stepwise increasing or decreasing manner. In one or more examples, the OTA is in a feedback loop to control the drain-source voltage of secondary transistor to generate a copy of a current at a primary transistor at the secondary transistor.

According to one or more examples, process 600 includes observing one or more of bandwidth or transconductance of the OTA while sweeping current generated by the current source at operation 604.

According to one or more examples, process 600 includes setting the current source to a current corresponding to one or more of an observed predetermined bandwidth or an observed predetermined transconductance at operation 606. An observed predetermined bandwidth is a bandwidth observed at operation 604 that is equal to or exceeds a predetermined value for bandwidth. An observed predetermined transconductance is a transconductance observed at operation 604 that is equal to or exceeds a predetermined value for transconductance.

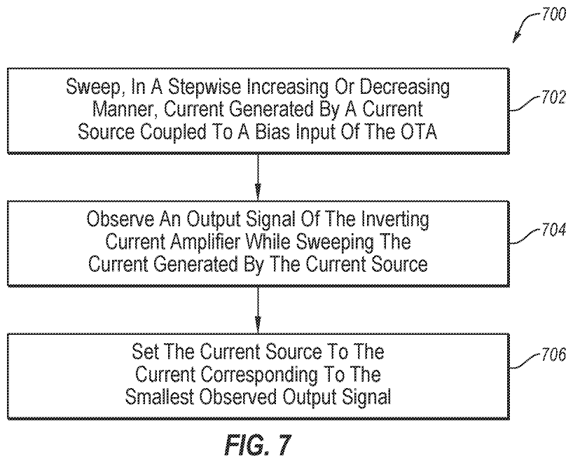

FIG. 7 is a flow-diagram depicting a process 700 to set the bandwidth of an OTA of a feedback loop utilized in an inverting current amplifier 100, in accordance with one or more examples.

Although the example process 700 depicts a particular sequence of operations, the sequence may be altered without departing from the scope of the present disclosure. For example, some of the operations depicted may be performed in parallel or in a different sequence that does not materially affect the function of the process 700. In other examples, different components of an example device or system that implements the process 700 may perform functions at substantially the same time or in a specific sequence.

According to one or more examples, process 700 includes sweeping, in a stepwise increasing or decreasing manner, current generated by the current source coupled to the bias input of the OTA at operation 702. In one or more examples, an amplitude of current generated by the current source is swept in a stepwise increasing or decreasing manner. In one or more examples, the OTA is in a feedback loop to control the drain-source voltage of secondary transistor to generate a copy of a current at a primary transistor at the secondary transistor.

According to one or more examples, process 700 includes observing an output signal of the inverting current amplifier while sweeping current generated by the current source at operation 704.

According to one or more examples, process 700 includes setting the current source to the current corresponding to the smallest observed output signal.

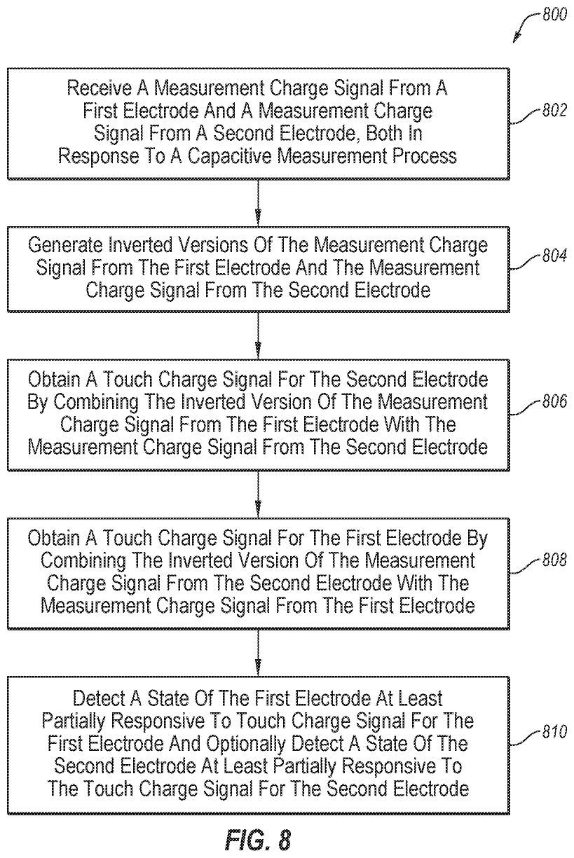

FIG. 8 is a flow-diagram depicting a process 800 to determine a state of an electrode of a capacitive sensor that includes cancelling a baseline charge signal from a measurement charge signal, in accordance with one or more examples.

Although the example process 800 depicts a particular sequence of operations, the sequence may be altered without departing from the scope of the present disclosure. For example, some of the operations depicted may be performed in parallel or in a different sequence that does not materially affect the function of the process 800. In other examples, different components of an example device or system that implements the process 800 may perform functions at substantially the same time or in a specific sequence.

According to one or more examples, process 800 includes receiving a measurement charge signal from a first electrode and a measurement charge signal from a second electrode, both in response to a capacitive measurement process at operation 802. The first electrode and second electrode are neighboring electrodes.

According to one or more examples, process 800 includes generating inverted versions of the measurement charge signal from the first electrode and measurement charge signal from the second electrode at operation 804.

According to one or more examples, process 800 includes obtaining a touch charge signal for the second electrode by combining the inverted version of the measurement charge signal from the first electrode with the measurement charge signal from the second electrode at operation 806.

According to one or more examples, process 800 includes obtaining a touch charge signal for the first electrode by combining the inverted version of the measurement charge signal from the second electrode with the measurement charge signal from the first electrode at operation 808.

According to one or more examples, process 800 includes detecting a state of the first electrode at least partially responsive to touch charge signal for the first electrode, and optionally detecting a state of the second electrode at least partially responsive to the touch charge signal for the second electrode at operation 810. In one or more examples, a detected states of the first electrode or the second electrode may include contact (i.e., a touch event) or no contact (i.e., no touch event).

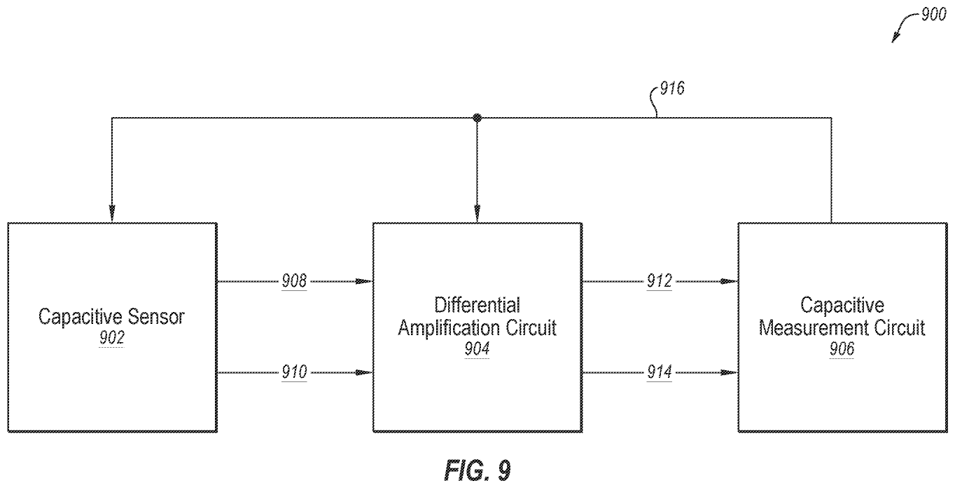

FIG. 9 is a block-diagram depicting a system 900 to sense touch via capacitance, in accordance with one or more examples. System 900 may also be referred to herein as a “capacitive touch sensing system 900.”

System 900 includes capacitive sensor 902, differential amplification circuit 904 and capacitive measurement circuit 906.

Capacitive sensor 902 is or includes rows and columns of touch electrodes. Respective electrodes of capacitive sensor 902 generate measurement charge signals at least partially responsive to a capacitive measurement process. When operations of such a capacitive measurement process are performed, measurement charge signals are generated by capacitive sensor 902 that have a known or predetermined relationship to capacitances of electrodes of capacitive sensor 902. The measurement charge signals can be read or processed to determine capacitances of electrodes of capacitive sensor 902 and determine a state of capacitive sensor 902 as discussed above.

Differential amplification circuit 904 is or includes one or more differential amplification circuits of FIG. 4 or FIG. 5 (e.g., first amp circuit 434, or second amp circuit 436, without limitation). Differential amplification circuit 904 receives measurement charge signals from capacitive sensor 902 and generates changed measurement charge signals provided to capacitive measurement circuit 906. More specifically, differential amplification circuit 904 receives a first measurement charge signal 908 and a second measurement charge signal 910, which it combines as discussed above to cancel baseline signals present in first measurement charge signal 908 and second measurement charge signal 910 and obtain changed first measurement charge signal 912 and changed second measurement charge signal 914. Changed first measurement charge signal 912 and changed second measurement charge signal 914 thus include only the touch signals present in first measurement charge signal 908 and second measurement charge signal 910.

Capacitive measurement circuit 906 is a logic circuit, and controls a capacitive measurement process via capacitive measurement process control signals 916 to cause capacitive sensor 902 to generates measurement charge signals such as first measurement charge signal 908 and second measurement charge signal 910, and changed measurement charge signals such as changed first measurement charge signal 912 and changed second measurement charge signal 914. Capacitive measurement circuit 906 processes changed first measurement charge signal 912 and changed second measurement charge signal 914 to measure a capacitance experienced by capacitive sensor 902 at least partially responsive to one or more of changed first measurement charge signal 912 and changed second measurement charge signal 914.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.” As used herein, “each” means some or a totality. As used herein, “each and every” means a totality.

Any characterization in this description of something as “typical,” “conventional,” “known,” or the like does not necessarily mean that it is disclosed in the prior art or that the discussed aspects are appreciated in the prior art. Nor does it necessarily mean that, in the relevant field, it is widely known, well-understood, or routinely used. Such characterizations should be understood to mean “known to the inventor(s) of this disclosure.”

Additional non-limiting examples of this disclosure include:

Example 1: An apparatus, comprising: a first transistor and a second transistor to provide a controlled current at the second transistor that is a copy of current at the first transistor when respective drain-source voltages of the first transistor and the second transistor are substantially equal; and a feedback loop to set the respective drain-source voltages of the first transistor and the second transistor to be substantially equal, wherein a responsiveness of the feedback loop is proportional to a set transconductance of an operational transconductance amplifier (OTA) of the feedback loop.

Example 2: The apparatus according to Example 1, wherein the feedback loop comprises: a pass transistor; and the OTA, wherein the OTA to set a drain-source voltage of the pass transistor utilizing an output voltage generated by the OTA.

Example 3: The apparatus according to Examples 1 and 2, wherein the OTA sets the drain-source voltage of the pass transistor is at least partially responsive to a relationship between voltages at respective drains of the first transistor and the second transistor.

Example 4: The apparatus according to Examples 1 to 3, wherein one of an inverting or non-inverting input of the OTA receives a drain voltage of the first transistor, and the other one of the inverting input or the non-inverting input of the OTA receives a drain voltage of the second transistor.

Example 5: The apparatus according to Examples 1 to 4, wherein the feedback loop comprises: a controlled current source coupled with a bias input of the OTA.

Example 6: The apparatus according to Examples 1 to 5, wherein the controlled current source is a variable current source to generate a current proportional to a control signal.

Example 7: The apparatus according to Examples 1 to 6, comprising: a further first transistor and a further second transistor to provide the controlled current at the further second transistor that is a copy of current at the further first transistor when the respective drain-source voltages of the further first transistor and the further second transistor are substantially equal; a further feedback loop to set respective source voltages of the further first transistor and the further second transistor to be substantially equal; and a translinear loop to provide a DC bias current to the first transistor and the further first transistor.

Example 8: The apparatus according to Examples 1 to 7, wherein the further first transistor and the further second transistor to provide the controlled current at the further second transistor at least partially responsive to input current received at an input terminal of the apparatus exhibiting a first current direction, wherein the first transistor and the second transistor to provide the controlled current at the second transistor at least partially responsive to the input current received at the input terminal of the apparatus exhibiting a second current direction, wherein the second current direction is different than the first current direction.

Example 9: The apparatus according to Examples 1 to 8, wherein: the first transistor and the second transistor are PMOS transistors; and the further first transistor and the further second transistor are NMOS transistors.

Example 10: The apparatus according to Examples 1 to 9, wherein respective sources of the first transistor and the second transistor to receive a first supply voltage, and wherein the respective sources of the further first transistor and the further second transistor to receive a second supply voltage, wherein the first supply voltage and the second supply voltage are different.

Example 11: An apparatus, comprising: a first current amplification circuit to receive an input current from a first touch electrode; and a second current amplification circuit to receive an input current from a second touch electrode, wherein the first current amplification circuit comprises: a current amplifier to amplify the input current received from the first touch electrode; an inverting current amplifier to invert the amplified input current with gain≥(−0.99); and a summer to combine the amplified input current and an inverted amplified input current generated at the second current amplification circuit.

Example 12: The apparatus according to Example 11, wherein the second current amplification circuit comprises: a respective current amplifier to amplify the input current received from the second touch electrode; the respective inverting current amplifier to invert the amplified input current; and the respective summer to combine the amplified input current and the inverted amplified input current generated at the first current amplification circuit.

Example 13: The apparatus according to Examples 11 and 12, wherein the inverting current amplifier of the first current amplification circuit comprises: a first transistor and a second transistor to provide controlled current at the second transistor that is a copy of current at the first transistor when respective drain-source voltages of the first transistor and the second transistor are substantially equal; and a feedback loop to set the respective drain-source voltages of the first transistor and the second transistor to be substantially equal.

Example 14: The apparatus according to Examples 11 to 13, wherein the feedback loop comprises: an operational transconductance amplifier (OTA) having a controlled bandwidth.

Example 15: The apparatus according to Examples 11 to 14, wherein a responsiveness of the feedback loop is proportional to the set bandwidth of the OTA.

Example 16: The apparatus according to Examples 11 to 15, wherein a bandwidth of the inverting current amplifier of the first current amplification circuit is set by a control signal.

Example 17: The apparatus according to Examples 11 to 16, wherein: a first component charge of current from the first touch electrode is proportional to a self-capacitance of the first touch electrode; and second component charge of current from the first touch electrode is proportional to a projected capacitance of the first touch electrode.

Example 18: The apparatus according to Examples 11 to 17, wherein: a first component charge of current from the second touch electrode is proportional to a self-capacitance of the second touch electrode; and a second component charge of current from the second touch electrode is proportional to projected capacitance of the second touch electrode.

Example 19: The apparatus according to Examples 11 to 18, wherein the inverting current amplifier of the first current amplification circuit comprises: a first transistor and a second transistor to provide controlled current at the second transistor that is a copy of current at the first transistor when respective drain-source voltages of the first transistor and the second transistor are substantially equal; and a feedback loop to set the respective drain-source voltages of the first transistor and the second transistor to be substantially equal, wherein a responsiveness of the feedback loop is proportional to a set bandwidth of an OTA of the feedback loop.

Example 20: The apparatus according to Examples 11 to 19, wherein the first touch electrode and the second touch electrode respectively to generate currents indicative of respective capacitance at least partially responsive to a capacitive measurement process.

Example 21: A method, comprising: receiving a measurement charge signal from a first electrode and a measurement charge signal from a second electrode, both in response to a capacitive measurement process; generating inverted versions of the measurement charge signal received from the first electrode and the measurement charge signal from the second electrode; obtaining a touch charge signal for the second electrode by combining the inverted version of the measurement charge signal from the first electrode with the measurement charge signal from the second electrode; and detecting a state of the first electrode at least partially responsive to touch charge signal for the first electrode.

Example 22: The method according to Example 21, comprising: obtaining a touch charge signal for the first electrode by combining the inverted version of the measurement charge signal from the second electrode with the measurement charge signal from the first electrode; and detecting a state of the second electrode at least partially responsive to the touch charge signal for the second electrode.

Example 23: The method according to Examples 21 and 22, wherein the generating inverted versions of the measurement charge signal received from the first electrode and the measurement charge signal from the second electrode comprises: generating, via an inverting current amplifier, the inverted versions of the measurement charge signal received from the first electrode and the measurement charge signal from the second electrode.

Example 24: The method according to Examples 21 to 23, wherein the inverting current amplifier comprises: a first transistor and a second transistor to provide controlled current at the second transistor that is a copy of current at the first transistor when respective drain-source voltages of the first transistor and the second transistor are substantially equal; and a feedback loop to set the respective drain-source voltages of the first transistor and the second transistor to be substantially equal.

Example 25: The method according to Examples 21 to 24, wherein the feedback loop comprises: an operational transconductance amplifier (OTA) having a transconductance settable via a bias input of the OTA.

Example 26: A method, comprising: setting respective drain voltages of a first transistor and a second transistor to be substantially equal utilizing an operational transconductance amplifier (OTA) having a set bandwidth; and providing a controlled current at the second transistor that is a copy of a current at the first transistor when respective drain-source voltages of the first transistor and the second transistor are substantially equal.

Example 27: The method according to Example 26, comprising: sweeping, in a stepwise increasing or decreasing manner, the current generated by a tuning current source coupled to a bias input of the OTA; observing one or more of bandwidth or transconductance of the OTA while sweeping the current generated by the current source; and setting the current source to a current corresponding to one or more of an observed predetermined bandwidth or an observed predetermined transconductance.

Example 28: The method according to Examples 26 and 27, comprising: sweeping, in a stepwise increasing or decreasing manner, the current generated by a current source coupled to a bias input of the OTA; observing an output signal at least partially based on the controlled current at the second transistor while sweeping the current generated by the current source; and setting the current source to the current corresponding to the smallest observed output signal.

While this disclosure includes certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
a first transistor and a second transistor to provide a controlled current at the second transistor that is a copy of current at the first transistor when respective drain-source voltages of the first transistor and the second transistor are substantially equal; and
a feedback loop to set the respective drain-source voltages of the first transistor and the second transistor to be substantially equal, wherein a responsiveness of the feedback loop is proportional to a set transconductance of an operational transconductance amplifier (OTA) of the feedback loop.

2. The apparatus of claim 1, wherein the feedback loop comprises:
a pass transistor; and
the OTA, wherein the OTA to set a drain-source voltage of the pass transistor utilizing an output voltage generated by the OTA.

3. The apparatus of claim 2, wherein the OTA sets the drain-source voltage of the pass transistor is at least partially responsive to a relationship between voltages at respective drains of the first transistor and the second transistor.

4. The apparatus of claim 2, wherein one of an inverting or non-inverting input of the OTA receives a drain voltage of the first transistor, and the other one of the inverting input or the non-inverting input of the OTA receives a drain voltage of the second transistor.

5. The apparatus of claim 2, wherein the feedback loop comprises:
a controlled current source coupled with a bias input of the OTA.

6. The apparatus of claim 5, wherein the controlled current source is a variable current source to generate a current proportional to a control signal.

7. The apparatus of claim 1, comprising:
a further first transistor and a further second transistor to provide the controlled current at the further second transistor that is a copy of current at the further first transistor when the respective drain-source voltages of the further first transistor and the further second transistor are substantially equal;
a further feedback loop to set respective source voltages of the further first transistor and the further second transistor to be substantially equal; and
a translinear loop to provide a DC bias current to the first transistor and the further first transistor.

8. The apparatus of claim 7, wherein the further first transistor and the further second transistor to provide the controlled current at the further second transistor at least partially responsive to input current received at an input terminal of the apparatus exhibiting a first current direction, wherein the first transistor and the second transistor to provide the controlled current at the second transistor at least partially responsive to the input current received at the input terminal of the apparatus exhibiting a second current direction, wherein the second current direction is different than the first current direction.

9. The apparatus of claim 8, wherein:
the first transistor and the second transistor are PMOS transistors; and
the further first transistor and the further second transistor are NMOS transistors.

10. The apparatus of claim 9, wherein respective sources of the first transistor and the second transistor to receive a first supply voltage, and wherein the respective sources of the further first transistor and the further second transistor to receive a second supply voltage, wherein the first supply voltage and the second supply voltage are different.

11. An apparatus, comprising:
a first current amplification circuit to receive an input current from a first touch electrode; and
a second current amplification circuit to receive an input current from a second touch electrode,
wherein the first current amplification circuit comprises:
a current amplifier to amplify the input current received from the first touch electrode;
an inverting current amplifier to invert the amplified input current with gain≥(−0.99); and
a summer to combine the amplified input current and an inverted amplified input current generated at the second current amplification circuit.

12. The apparatus of claim 11, wherein the second current amplification circuit comprises:
a respective current amplifier to amplify the input current received from the second touch electrode;
the respective inverting current amplifier to invert the amplified input current; and
the respective summer to combine the amplified input current and the inverted amplified input current generated at the first current amplification circuit.

13. The apparatus of claim 11, wherein the inverting current amplifier of the first current amplification circuit comprises:
a first transistor and a second transistor to provide controlled current at the second transistor that is a copy of current at the first transistor when respective drain-source voltages of the first transistor and the second transistor are substantially equal; and
a feedback loop to set the respective drain-source voltages of the first transistor and the second transistor to be substantially equal.

14. The apparatus of claim 13, wherein the feedback loop comprises:
an operational transconductance amplifier (OTA) having a controlled bandwidth.

15. The apparatus of claim 14, wherein a responsiveness of the feedback loop is proportional to the set bandwidth of the OTA.

16. The apparatus of claim 11, wherein a bandwidth of the inverting current amplifier of the first current amplification circuit is set by a control signal.

17. The apparatus of claim 11, wherein:
a first component charge of current from the first touch electrode is proportional to a self-capacitance of the first touch electrode; and
second component charge of current from the first touch electrode is proportional to a projected capacitance of the first touch electrode.

18. The apparatus of claim 11, wherein:
a first component charge of current from the second touch electrode is proportional to a self-capacitance of the second touch electrode; and
a second component charge of current from the second touch electrode is proportional to projected capacitance of the second touch electrode.

19. The apparatus of claim 11, wherein the inverting current amplifier of the first current amplification circuit comprises:
a first transistor and a second transistor to provide controlled current at the second transistor that is a copy of current at the first transistor when respective drain-source voltages of the first transistor and the second transistor are substantially equal; and
a feedback loop to set the respective drain-source voltages of the first transistor and the second transistor to be substantially equal, wherein a responsiveness of the feedback loop is proportional to a set bandwidth of an OTA of the feedback loop.

20. The apparatus of claim 11, wherein the first touch electrode and the second touch electrode respectively to generate currents indicative of respective capacitance at least partially responsive to a capacitive measurement process.

21. A method, comprising:
receiving a measurement charge signal from a first electrode and a measurement charge signal from a second electrode, both in response to a capacitive measurement process;
generating inverted versions of the measurement charge signal received from the first electrode and the measurement charge signal from the second electrode;
obtaining a touch charge signal for the second electrode by combining the inverted version of the measurement charge signal from the first electrode with the measurement charge signal from the second electrode; and
detecting a state of the first electrode at least partially responsive to touch charge signal for the first electrode.

22. The method of claim 21, comprising:
obtaining a touch charge signal for the first electrode by combining the inverted version of the measurement charge signal from the second electrode with the measurement charge signal from the first electrode; and
detecting a state of the second electrode at least partially responsive to the touch charge signal for the second electrode.

23. The method of claim 21, wherein the generating inverted versions of the measurement charge signal received from the first electrode and the measurement charge signal from the second electrode comprises:
generating, via an inverting current amplifier, the inverted versions of the measurement charge signal received from the first electrode and the measurement charge signal from the second electrode.

24. The method of claim 23, wherein the inverting current amplifier comprises:
a first transistor and a second transistor to provide controlled current at the second transistor that is a copy of current at the first transistor when respective drain-source voltages of the first transistor and the second transistor are substantially equal; and
a feedback loop to set the respective drain-source voltages of the first transistor and the second transistor to be substantially equal.

25. The method of claim 24, wherein the feedback loop comprises:
an operational transconductance amplifier (OTA) having a transconductance settable via a bias input of the OTA.

26. A method, comprising:
setting respective drain voltages of a first transistor and a second transistor to be substantially equal utilizing an operational transconductance amplifier (OTA) having a set bandwidth; and
providing a controlled current at the second transistor that is a copy of a current at the first transistor when respective drain-source voltages of the first transistor and the second transistor are substantially equal.

27. The method of claim 26, comprising:
sweeping, in a stepwise increasing or decreasing manner, the current generated by a tuning current source coupled to a bias input of the OTA;
observing one or more of bandwidth or transconductance of the OTA while sweeping the current generated by the current source; and
setting the current source to a current corresponding to one or more of an observed predetermined bandwidth or an observed predetermined transconductance.

28. The method of claim 26, comprising:
sweeping, in a stepwise increasing or decreasing manner, the current generated by a current source coupled to a bias input of the OTA;
observing an output signal at least partially based on the controlled current at the second transistor while sweeping the current generated by the current source; and
setting the current source to the current corresponding to the smallest observed output signal.
